(19) United States
(12) Patent Application Publication
(10) Pub. No.: US 2024/0273769 A1
(43) Pub. Date: Aug. 15, 2024

(54) Systems and Methods for Performing Progressive Mesh Compression

(71) Applicant: Six Impossible Things Before Breakfast Limited, Dublin (IE)

(72) Inventor: Sherry IGNATCHENKO, Weidling (AT)

(73) Assignee: Six Impossible Things Before Breakfast Limited, Dublin (IE)

(21) Appl. No.: 18/438,898

(22) Filed: Feb. 12, 2024

Related U.S. Application Data
(60) Provisional application No. 63/484,689, filed on Feb. 13, 2023.

(51) Int. Cl. G06T 9/00; G06T 17/20; G06T 19/20

(52) U.S. Cl. CPC G06T 9/001; G06T 17/205; G06T 19/20; G06T 2210/36; G06T 2210/56; G06T 2219/2021

(57) ABSTRACT

The systems and methods described herein may improve the rendering of computer-generated three-dimensional models using progressive mesh compression. In various implementations, an initial mesh may be obtained and encoded into a data stream. Subsequent meshes may then be encoded based on a superset relationship between consecutive meshes. If the vertices of the mesh are not a superset of a prior mesh, the mesh may be encoded within an intermediate symbol stream using a non-incremental mesh compression technique. If the vertices of the mesh are a superset of a prior mesh, a sequence of per-triangle operators may be applied to the mesh to produce a progressive mesh. The mesh may then be encoded by encoding the operators applied to the mesh in sequence. When encoding the mesh, coordinates of vertices may be defined based on the difference between the coordinates and predicted values generated using a prediction function.

### RELATED APPLICATIONS

This application claims priority to U.S. Provisional Application No. 63/484,689, entitled “Method for Progressive Mesh Compression,” filed on Feb. 13, 2023, the content of which is hereby incorporated herein by reference in its entirety.

### FIELD OF THE DISCLOSURE

The systems and methods described herein relate to improvements to the compression of meshes used to render computer-generated three-dimensional models.

### BACKGROUND

In computer graphics, meshes consisting of hundreds or thousands of triangles (or other polygons) are frequently used to render three-dimensional models. A technique known as “level of details” (or “LODs”) is frequently used to compress and decompress these computer-generated three-dimensional models. LODs essentially is a sequence of meshes, which may be ordered from highest-quality to lowest-quality, and which are used to show a 3D model with a different number of triangles (usually at different distances). When transferring meshes over the network, meshes in general and LODs in particular compression is used. One widely used method for addressing mesh compression is “Draco compression.”

Draco compression is a compression technique that uses mesh to improve storage and transmission of meshes. Draco compression works by compressing meshes with connectivity information, texture coordinates, color information, normal vectors, and any other generic attributes associated with a mesh's geometry. When used in the context of LODs, which often have to be shown one after the other (from lowest-quality to highest-quality, for example, when an object which uses the mesh moves towards the camera), Draco and other similar single-mesh compressing methods, have a drawback—they do not use all the information available during compression and decompression of the data; specifically, Draco and other similar single-mesh compressing methods are not able to use information about lower-quality LOD when decompressing higher-quality one. Such a sequence of LODs, compressed in the order from lowest-quality to highest-quality, is known as “progressive mesh” compression; while progressive mesh compression methods do exist, existing ones (such as discussed in “Progressive compression of manifold polygon meshes” by Adrien Maglo et al., which was published in Computer & Graphics, Vol. 36, Issue 5 in August 2012 (pp. 349-359)) tend to concentrate on the mathematical part of the compression problem rather than on bit-encoding part, which leads to inefficiencies. As such, there is a need in the art for improved technique(s) for compressing and decompressing progressive meshes that allows the information in the compressed progressive meshes to be used much more efficiently when transmitting or storing computer-generated three-dimensional models.

### SUMMARY OF THE DISCLOSURE

This disclosure relates to systems and methods for compressing meshes used to render three-dimensional models in computer-generated graphics. According to one aspect of the invention, the systems and methods described herein may compress meshes of three-dimensional models using progressive mesh compression. In various implementations, an initial mesh may be obtained and encoded into a data stream. For example, the initial mesh may be encoded within an intermediate symbol stream. Subsequent meshes may then be encoded based on a superset relationship between consecutive meshes. For example, when encoding a subsequent mesh, whether vertices of that mesh are a superset of the vertices of a previous mesh may be determined. If the vertices of the mesh are not a superset of a prior mesh, the mesh may be encoded within an intermediate symbol stream using a non-incremental mesh compression technique. If the vertices of the mesh are a superset of a prior mesh, a sequence of per-triangle, per-edge, or per-vertex operators may be applied to the mesh to produce a progressive mesh. In various implementations, the operators may include an “add quantization bits” operator, an “add vertex” operator, an “add multiple vertices” operator, a “move vertex” operator, and/or one or more other operators. The mesh may then be encoded by encoding the operators applied to the mesh in sequence. When encoding the mesh, coordinates of vertices may be defined based on the difference between the coordinates and the predicted values generated using a prediction function. In various implementations, the operators (and operator-specific data) may be encoded in sequence into the intermediate symbol stream.

According to another aspect of the invention, the systems and methods described herein may compress meshes using differential mesh compression. In various implementations, one or more per-triangle, per-edge, or per-vertex operators may be applied to an initial mesh to produce a differentially compressed mesh. In various implementations, the initial mesh may comprise a morphed mesh. When encoding the sequence of per-triangle (and/or per-edge or per-vertex) operators applied to the initial mesh into an intermediate symbol stream, coordinates of the differentially compressed mesh may be encoded as a difference from the vertices of the initial mesh. For example, coordinates corresponding to moved vertices in the differentially compressed mesh may be encoded using a delta value (or difference) from corresponding vertices in the initial mesh. In various implementations, the delta value may be calculated differentially from the previous delta value. For example, the difference between the coordinates of a moved vertex and coordinates of the vertex in the initial mesh may be encoded based on a previous difference encoded. In some implementations, the indexes of the moved vertices in the differentially compressed mesh may not be encoded at all.

According to another aspect of the invention, the systems and methods described herein may compress skinned meshes using progressive mesh compression. In various implementations, an initial skinned mesh may be compressed using one or more techniques described herein, with the addition of a per-vertex array of (bone_index, bone_weight) pairs. In various implementations, (bone_index, bone_weight) pairs for skinned meshes may be compressed using a per-bone prediction function. For example, a per-bone prediction function over 3D space may be defined that corresponds to a Gaussian function (described, for example, by zero expected value and some variance), a 3D vector (described, for example, by its origin and direction), and/or a radius of a cylinder. The per-bone prediction function may be configured to predict values that may be used to encode vertices of a progressive mesh generated based on the initial skinned mesh.

According to another aspect of the invention, the systems and methods described herein may compress meshes using algebraic surface prediction. In various implementations, these meshes may be compressed in a non-incremental manner. For example, a traversing algorithm (such as Edgebreaker) may be used to traverse and encode the topology of a mesh, and a parallelogram predictor may be used to predict coordinates of new vertices as the new vertices are added to the mesh. In some implementations, this technique may be improved by using the parallelogram predictor to predict an (X, Y) coordinate pair of a new vertex, and using coordinates of the vertices used by the parallelogram predictor and/or their respective normal vectors to calculate an algebraic surface (such as 2^{nd}- or 3^{rd}-order surface) which goes through these three vertices and has appropriate normals at the respective points. When this surface is calculated, an intersection of the normal vector to the parallelogram at the point (X, Y) and the calculated surface may be found, and the distance between this intersection and the plane of the parallelogram may comprise a predicted Z-coordinate for encoding.

These and other objects, features, and characteristics of the systems and/or methods disclosed herein, as well as the methods of operation and functions of the related elements of structure and the combination thereof, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of “a”, “an”, and “the” include plural referents unless the context clearly dictates otherwise.

### BRIEF DESCRIPTION OF THE DRAWINGS

The present invention is illustrated by way of example and not limited in the accompanying figures in which like reference numerals indicate similar elements and in which:

FIG. 1 depicts a block diagram of an example of a system configured to compressing a three-dimensional model using progressive mesh compression, according to one or more aspects described herein;

FIG. 2 depicts a diagram illustrating an example sequence of meshes in which the number of meshes (or triangles) gradually increases as the meshes move from the lowest quality mesh to the highest-quality mesh, according to one or more aspects described herein;

FIG. 3 depicts a flow diagram of an example of a method for performing progressive mesh compression for a three-dimensional model based on a superset relationship between consecutive meshes, according to one or more aspects described herein;

FIG. 4 illustrates a predicted vertex added to a mesh comprising an (X, Y) coordinate pair and a Z-coordinate which may be predicted separately, according to one or more aspects described herein;

FIG. 5 illustrates a predicted Z-coordinate for a vertex that is defined based on a distance from a triangle plane, according to one or more aspects described herein;

FIGS. 6A-C illustrate operations to add multiple vertices to a triangle of a mesh, according to one or more aspects described herein; and

FIG. 7 depicts a flow diagram of an example of a method for compressing meshes using differential mesh compression, according to one or more aspects described herein.

These drawings are provided for purposes of illustration only and merely depict typical or example embodiments. These drawings are provided to facilitate the reader's understanding and shall not be considered limiting of the breadth, scope, or applicability of the disclosure. For clarity and ease of illustration, these drawings are not necessarily drawn to scale.

### DETAILED DESCRIPTION

Certain illustrative aspects of the systems and methods according to the present invention are described herein in connection with the following description and the accompanying figures. These aspects are indicative, however, of but a few of the various ways in which the principles of the invention may be employed and the present invention is intended to include all such aspects and their equivalents. Other advantages and novel features of the invention may become apparent from the following detailed description when considered in conjunction with the figures.

In the following detailed description, numerous specific details are set forth in order to provide a thorough understanding of the invention. In other instances, well known structures, interfaces, and processes have not been shown in detail in order not to unnecessarily obscure the invention. However, it will be apparent to one of ordinary skill in the art that those specific details disclosed herein need not be used to practice the invention and do not represent a limitation on the scope of the invention, except as recited in the claims. It is intended that no part of this specification be construed to effect a disavowal of any part of the full scope of the invention. Although certain embodiments of the present disclosure are described, these embodiments likewise are not intended to limit the full scope of the invention.

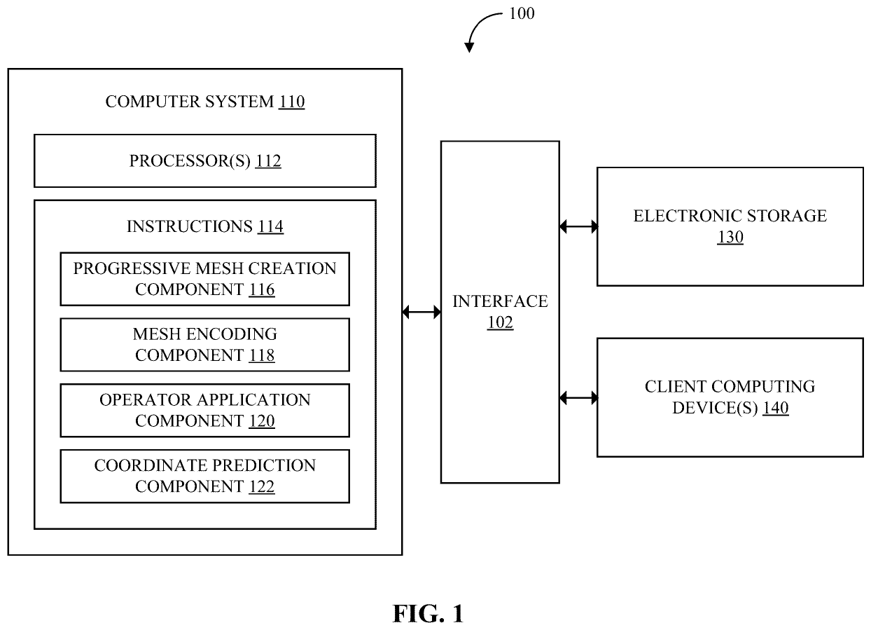

FIG. 1 illustrates an example of a system 100 for compressing computer-generated three-dimensional models, according to one or more aspects described herein. In various implementations, system 100 may include one or more of interface 102, a computer system 110, electronic storage 130, client computing device(s) 140, and/or other components. In various implementations, computer system 110 may include one or more physical processors 112 (also interchangeably referred to herein as processor(s) 112, processor 112, or processors 112 for convenience), computer readable instructions 114, and/or one or more other components. In some implementations, system 100 may include one or more external resources, such as sources of information outside of system 100, external entities participating with system 100, and/or other resources. In various implementations, system 100 may be configured to receive input from or otherwise interact with one or more users via one or more client computing device(s) 140.

In various implementations, physical processor(s) 112 may be configured to provide information processing capabilities in system 100. As such, the processor(s) 112 may comprise one or more of a digital processor, an analog processor, a digital circuit designed to process information, a central processing unit, a graphics processing unit, a microcontroller, a microprocessor, a field programmable gate array (FPGA), an application specific integrated circuit (ASIC), a System on a Chip (SoC), and/or other mechanisms for electronically processing information. Processor(s) 112 may be configured to execute one or more computer readable instructions 114. Computer readable instructions 114 may include one or more computer program components. In various implementations, computer readable instructions 114 may include one or more of progressive mesh creation component 116, mesh encoding component 118, operator application component 120, coordinate prediction component 122, and/or other computer program components. As used herein, for convenience, the various computer readable instructions 114 will be described as performing an operation, when, in fact, the various instructions program the processor(s) 112 (and therefore system 100) to perform the operation.

In various implementations, progressive mesh creation component 116 may be configured to obtain or generate a sequence of meshes to be used to create a progressive mesh. A progressive mesh (or progressive stream) may be used to render a series or sequence of meshes of gradually-increasing quality. In various implementations, a progressive mesh may be implemented in an intermediate symbol stream. When implemented in an “intermediate symbol stream” (which when referred to herein is referencing the one or more techniques described in U.S. patent application Ser. No. 18/438,702, entitled “SYSTEMS AND METHODS FOR IMPROVING COMPRESSION OF STRUCTURED DATA IN THREE-DIMENSIONAL APPLICATIONS,” filed Feb. 12, 2024, the content of which is hereby incorporated by reference herein in its entirety), the intermediate symbol stream may include information about a lowest-quality mesh (or base mesh) first followed by subsequent meshes of gradually increasing quality that may be encoded by referencing a preceding mesh or the base mesh.

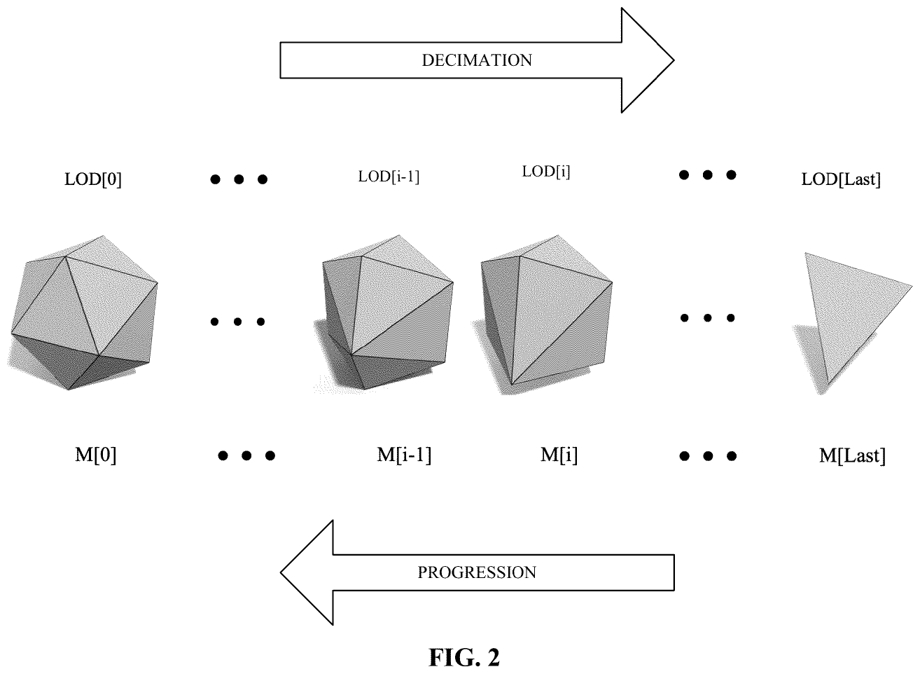

In various implementations, progressive mesh creation component 116 may be configured to receive or obtain an initial (or base) mesh for a computer-generated three-dimensional model. In various implementations, progressive mesh creation component 116 may be configured to obtain the base mesh from a sequence of meshes. For example, in some implementations, progressive mesh creation component 116 may be configured to obtain or generate a sequence of meshes comprising the base mesh. In some implementations, the sequence of meshes may be derived from a mesh to be used to render a computer-generated three-dimensional model. That mesh may then be repeatedly compressed, downsized, decimated, or otherwise reduced in quality to produce a sequence of meshes with a gradually decreasing mesh count (or number of the meshes). For example, the sequence of meshes may be created using decimation, which doesn't change vertex coordinates, only removes them (for example, as described in “A General Framework for Mesh Decimation” by Leif Kobbelt et al., which was published in Proceedings of the Graphics Interface in 1998, the content of which is hereby incorporated by reference herein in its entirety). The initial mesh from which the sequence of meshes was derived-which is also highest quality mesh in the sequence of meshes—may be referred to herein as “M[0]”, and the last mesh in the sequence of meshes which comprises the lowest-quality mesh may be referred to herein as “M[Last]”. As an example, FIG. 2 depicts an example sequence of meshes in which the number of meshes (or triangles) gradually decreases as the meshes move from the highest-quality mesh (e.g., M[0]) to the lowest-quality mesh (e.g., M[Last]). This sequence of meshes may then be encoded (and compressed) beginning with the lowest-quality mesh (M[Last]) and subsequently encoding each additional mesh as the meshes increase in quality.

In some implementations, the sequence of meshes may comprise a sequence of levels of detail (or LODs), which may include meshes and/or textures (including normal maps). As used herein, “LOD[0]” may be used to denote a highest-quality LOD, and “LOD[Last]” may be used to denote a lowest-quality LOD. In turn, “LOD[1]” may be used to denote a second-highest-quality LOD, and “LOD[Last-1]” may be used to denote a second-lowest-quality LOD, and so on. Similarly, M[i-1] may be used to denote a (i-1)^{th} mesh, and M[i] may be used to denote a (i)^{th} mesh. As depicted in FIG. 2, notation is being used when incrementing index i while performing decimation, and therefore i is decremented while performing progressive compression.

In various implementations, mesh encoding component 118 may be configured to encode meshes described herein into an intermediate symbol stream consisting of symbols. For example, operators applied to triangles of a mesh may be encoded within an intermediate symbol stream using pre-defined symbols. In some implementations, operator-specific data may also be encoded within the intermediate symbol stream using pre-defined symbol and/or may be incorporated into symbols used to encode the operator to which they correspond. For example, operator “add vertex” may include operator-specific data such as “triangle number in traversing order” (where the vertex should be added), and “offset” (3D offset from the predicted value of the vertex for this triangle, see details on traversing order and on predictions below). In various implementations, mesh encoding component 118 may be configured to compress the intermediate symbol stream using one or more entropy encoding methods. For example, the one or more entropy encoding methods may comprise Huffman encoding, arithmetic coding, one of the asymmetric numeral systems (ANS) family of entropy encoding methods, and/or one or more other entropy encoding methods. As referred to herein, the ANS family of entropy encoding methods may include range asymmetric numeral systems (rANS), tabled asymmetrical numeral systems (tANS), finite state entropy (FSE), and/or one or more other similar entropy encoding methods. The compressed intermediate symbol stream may be referred to herein as a “compressed bitstream.”

In various implementations, mesh encoding component 118 may be configured to encode a base mesh having a smallest number of faces (e.g., the roughest mesh among the sequence of meshes) into an output data stream. In various implementations, a base mesh (“M[Last]”) may be encoded first before encoding subsequent meshes increasing in complexity. In various implementations, mesh encoding component 118 may be configured to encode information related to meshes, such as mesh connectivity, positions, and other attributes of the triangle meshes. In some implementation, mesh encoding component 118 may be configured to apply a non-incremental mesh compression technique when compressing the meshes; one important case for non-incremental compression is compressing the first mesh in the stream (M[Last]). For example, mesh encoding component 118 may be configured to apply Draco compression and/or other compression techniques described herein. In some implementation, mesh encoding component 118 may be configured to use a technique which derives a traversing order “O[Last]” from the mesh triangle; for example, this is doable for most Edgebreaker-based techniques—including Draco compression.

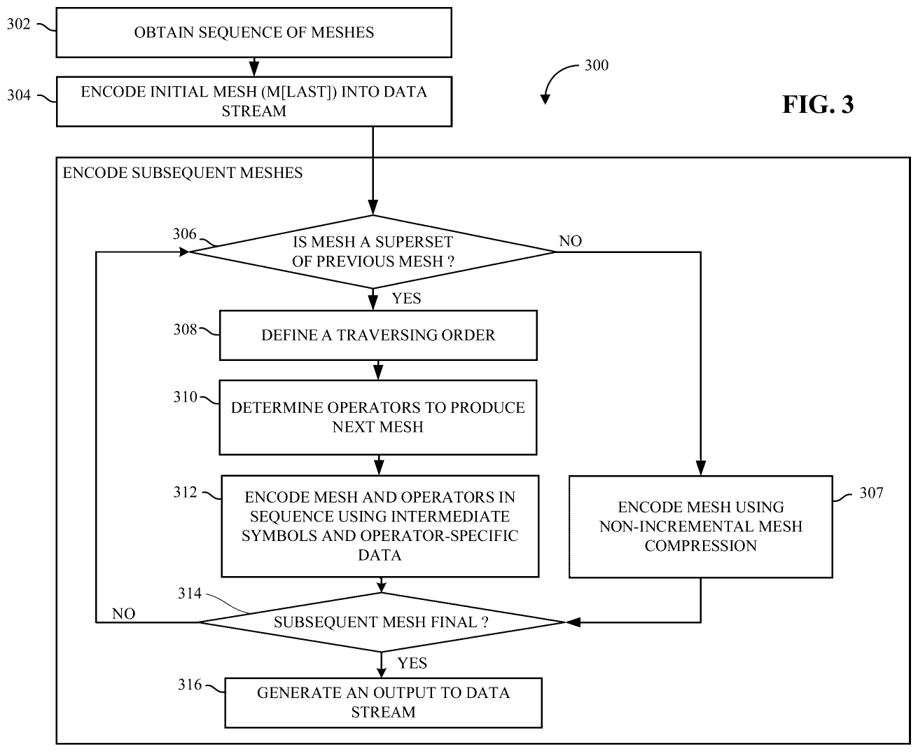

In various implementations, mesh encoding component 118 may be configured to encode subsequent meshes (after the base mesh) by evaluating the superset relationship of consecutive meshes. For example, if during decimation a vertex-removing method (such as the one described in “A General Framework for Mesh Decimation” by Leif Kobbelt et al., which was published in Proceedings of the Graphics Interface in 1998) was used, each mesh M1 which has lower index (i.e., resides towards the left side on FIG. 2) will have vertices which are strict superset of vertexes in any mesh M2 where M2 has higher index than M1 (i.e., to the right from M1 on FIG. 2). For example, mesh encoding component 118 may be configured to encode subsequent meshes by evaluating the superset relationship of consecutive meshes as described herein with respect to process 300 depicted in FIG. 3. In various implementations, mesh encoding component 118 may be configured to determine whether vertices of a subsequent mesh are a superset of the vertices of a previous mesh; in other implementations (where the only decimation used was a vertex-removing one), it can be assumed by design. In some other implementations, mesh encoding component 118 may be configured to determine whether the vertices of a subsequent mesh are mostly a superset of the vertices of the a preceding mesh; here, “mostly” is used to denote that even if some of the vertices (but relatively few) do not fall under “superset” rule, the methods described herein may still be used, just encoding non-superset vertices separately, and as long as their number is limited. The manner in which the non-superset vertices are encoded would not affect compression in a significant way (for example, the non-superset vertices may simply be encoded using techniques described in described in U.S. patent application Ser. No. 18/438,702, entitled “SYSTEMS AND METHODS FOR IMPROVING COMPRESSION OF STRUCTURED DATA IN THREE-DIMENSIONAL APPLICATIONS,” filed Feb. 12, 2024, the content of which is hereby incorporated by reference herein in its entirety).

If vertices of the mesh are not a superset of a previous mesh, mesh encoding component 118 may be configured to encode the mesh by using a non-incremental mesh compression technique. In some implementations, mesh encoding component 118 may be configured to calculate the mesh compressed size when using both incremental and non-incremental compression techniques. If using non-incremental mesh compression to compress a mesh would result in smaller compressed size, mesh encoding component 118 may be configured to encode that mesh using non-incremental mesh compression.

If vertices of the mesh are determined to be a superset of the vertices of the previous mesh, mesh encoding component 118 may be configured to define a traversing order. For example, when an initial mesh is encoded using a non-incremental method, vertices will typically be mentioned in some order within the compressed stream (even if some vertex is mentioned twice). In such implementations, only the first mention may be considered for the purposes of determining traversing order, and this order coming from non-incremental order may become the initial traversing order. Then, whenever a new vertex is added, the new vertex may be put at a well-defined place within the order; for example, the new vertex may be inserted right after one of the vertexes mentioned—implicitly or explicitly—within the operator which added it, or such new vertices may be added to the end of the traversing order. And once a traversing order for vertices is defined, a traversing order can also be defined for edges. For example, edges may be sorted by (traversing_order_of_first_edge_end, traversing_order_of_second_edge_end); traversing order for triangles may be defined in a similar manner. In some implementations, the edges or triangles may be taken as the traversing order obtained from the compressed stream, or two or all three of (vertex, edges, triangles) may be taken as the traversing orders from the compressed stream. In various implementations, mesh encoding component 118 may be configured to traverse all the triangles of the mesh in the triangle traversing order defined for the mesh. For each triangle, zero or more of the operators described herein with respect to operator application component 120 may be specified. As described herein, the operators may include an “add quantization bits” operator, an “add vertex” operator, an “add multiple vertices” operator, a “move vertex” operator, and/or one or more other operators. In various implementations, mesh encoding component 118 may be configured to encode each of the operators using its intermediate symbol along with operator-specific data. In some implementations, the intermediate symbols may be pre-defined and represent a state of a triangle mesh and its operators. In various implementations, mesh encoding component 118 may be configured to repeat these operations and encode each mesh and its operators in sequence to generate a progressive mesh.

In various implementations, operator application component 120 may be configured to apply one or more operators to a mesh. In various implementations, operator application component 120 may be configured to choose one or more pre-defined operators to apply in order to optimize a certain operation, as described further herein. The one or more operators may comprise an “add quantization bits” operator, an “add vertex” operator, an “add multiple vertices” operator, a “move vertex” operator, and/or one or more other operators. In various implementations, operator application component 120 may be configured to apply a sequence of per-triangle (or per-edge or per-vertex) operators to a mesh while the mesh is traversed in an order which is derived from the mesh or from an order for a prior mesh. As described herein, operators may define the operations to be applied to a single mesh to produce a next or subsequent mesh.

In some implementations, operator application component 120 may be configured to apply an “add quantization bits” operator to a mesh. For example, operator application component 120 may be configured to apply an “add quantization bits” operator to a mesh M[i] (note that according to notation on FIG. 2, when compressing progressively, the method goes from right to left, and from higher indexes to lower ones). In such implementations, the operator may contain additional quantization bits for the vertices of the current triangle; in other words, if some value was previously quantized to 9 bits, just one bit may be transferred for it (or one bit may be transferred for each coordinate of each vertex in the mesh), to increase number of quantizing bits (and therefore precision) for one element (or for the whole mesh).

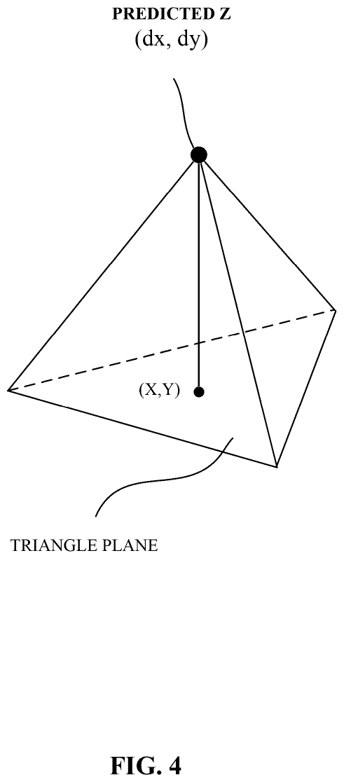

In some implementations, operator application component 120 may be configured to apply an “add vertex” operator to a mesh. For example, operator application component 120 may be configured to apply an “add vertex” operator to a mesh M[i]. In various implementations, the vertex added may include (X, Y, Z) coordinates generated using a prediction function ƒ(I, i-1). For example, coordinate prediction component 122 may be configured to generate (X, Y, Z) coordinates for a vertex to be added to a mesh. In various implementations, coordinate prediction component 122 may be configured to determine an (X, Y) pair and Z-coordinate for a vertex separately. For example, coordinate prediction component 122 may be configured to predict the (X, Y) coordinates of an added vertex as coordinates of the point within the triangle plane and predict the Z-coordinate separately as a distance from the triangle plane. For example, FIG. 4 illustrates a predicted vertex added to a mesh comprising an (X, Y) coordinate pair and a Z-coordinate which may be predicted separately, according to one or more aspects described herein. As shown in FIG. 4, coordinate prediction component 122 may be configured to predict an (X,Y) coordinate pair and a predicted Z-coordinate defined by specifying a distance “(dx, dy)” from the predicted (X, Y) coordinate pair. In some implementations, coordinate prediction component 122 may be configured to generate a predicted (X, Y) coordinate pair from any of the triangle centers of the triangle, where potential triangle centers may be calculated as described, for example, in “Triangle center,” Wikipedia, The Free Encyclopedia, Jan. 28, 2024 (last visited Feb. 11 2024), available at https://en.wikipedia.org/wiki/Triangle_center. In other implementations, coordinate prediction component 122 may be configured to encode two or more centers and reference data indicating which of the centers to be used with a symbol within the intermediate symbol stream.

In some implementations, coordinate prediction component 122 may be configured to calculate a predicted (X, Y) coordinate pair using height map and a UV-mapped coordinate (which may be used to associate this height map—or normal map from which height map is derived) of a pixel. For example, coordinate prediction component 122 may be configured to calculate a predicted (X, Y) coordinate pair based on the largest deviation from the plane (i.e., the highest point in the height map). In some implementations, this point—“H[i]”—may comprise the highest point in the height map (i.e., a global maximum) and the highest of the local maximums. In some implementations, this point—“H[i]”—may correspond to be a height map for ith LOD. In some implementations, coordinate prediction component 122 may be configured to calculate this height map H[i] from a normal map for ith LOD using one or more techniques described in U.S. patent application Ser. No. 18/425,130, entitled “SYSTEMS AND METHODS FOR IMPROVING COMPRESSION OF NORMAL MAPS,” filed Jan. 29, 2024, the content of which is hereby incorporated by reference herein in its entirety. In some implementations, coordinate prediction component 122 may be configured to calculate a distance from 2nd-largest-local-maximum, 3rd-largest-local-maximum, and so on—and specify which of largest maximums is used for reference; this may improve compression in cases when the vertex is added in the vicinity of 2^{nd}—etc. maximums. In some implementations, coordinate prediction component 122 may be configured to use H[i-1] or H[i].

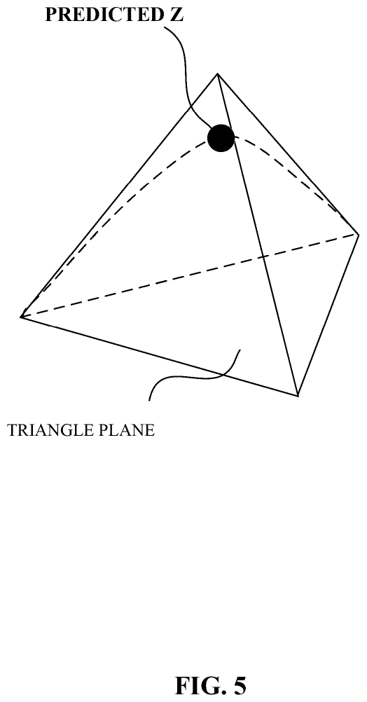

In various implementations, coordinate prediction component 122 may be configured to predict a Z-coordinate for a vertex to be added. For example, FIG. 5 illustrates a predicted Z-coordinate for a vertex that is defined based on a distance from a triangle plane, according to one or more aspects described herein. When coordinate prediction component 122 calculates a Z-coordinate, the Z-coordinate may be encoded using a distance from a triangle plane comprising the (X, Y) coordinate pair. In some implementations, the Z-coordinate may be encoded using a delta value (i.e., a difference) between an actual coordinate and a Z-coordinate predicted by coordinate prediction component 122. Encoding the delta value may be advantageous and optimal because the delta value may be relatively small in size when compared to the actual number. The number of bits used for encoding data may also be relatively small, thus increasing compression performance. In various implementations, coordinate prediction component 122 may similarly be configured to calculate a (X, Y) coordinate pair by taking a base (X, Y) coordinate pair and then applying a delta value to the base (X, Y) coordinate pair.

In some implementations, coordinate prediction component 122 may be configured to use a height map H[i] or H[i-1] for calculating a predicted Z-coordinate. In some implementations, coordinate prediction component 122 may be configured to calculate an intersection of the normal with the triangle at the point (X,Y). In various implementations, coordinate prediction component 122 may be configured to calculate a 3D spline surface over a mesh M[i] in order to calculate the predicted Z-coordinate. In some implementations, coordinate prediction component 122 may be configured to calculate an intersection of the normal with the triangle at the point (X,Y) using a 3D Bezier curve and/or N-patch calculated over the mesh M[i] to predict a Z-coordinate. In such implementations, the 3D Bezier curve may provide a parametric curve that may be used in computer graphics and related fields. In some implementations, coordinate prediction component 122 may be configured to use a normal map to predict a Z-coordinate of a vertex to be added. Accordingly, a subsequent mesh M[i-1] may be created using the techniques described herein based on a previous mesh M[i] and a previous traversing order O[i], plus optionally one or more of a previous height map H[i] and a previous normal map n[i]. In some embodiments, prediction methods described in “Progressive compression of manifold polygon meshes” by Adrien Maglo et al., which was published in Computer & Graphics, Vol. 36, Issue 5 in August 2012 (pp. 349-359) may be used.

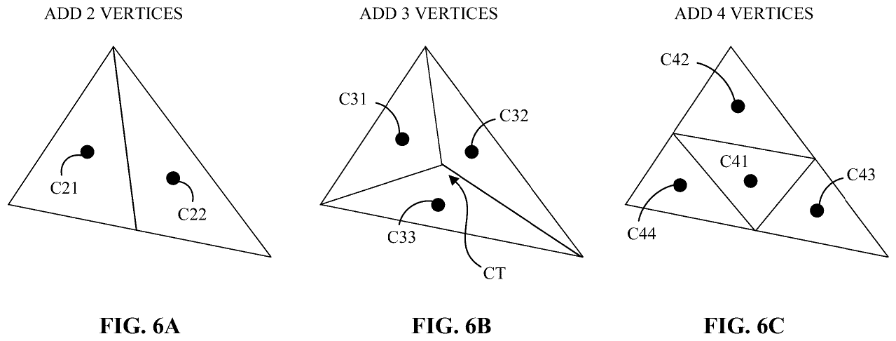

In some implementations, operator application component 120 may be configured to apply an “add multiple vertices” operator to a mesh. For example, operator application component 120 may be configured to apply an “add multiple vertices” operator to a mesh M[i]. In various implementations, the “add multiple vertices” operator may be used to generate better predictions for (X, Y) coordinate pairs for each of the added vertices. For example, as shown in FIG. 6A, operator application component 120 may be configured to add two vertices. In such cases, operator application component 120 may be configured to split a current triangle in two. In some implementations, operator application component 120 may be configured to use a median or bisect to split a side/corner of the current triangle. In some implementations, operator application component 120 may be configured to indicate which method was used to split the triangle by encoding the number of edge(s)/corner(s) as a symbol. For example, information may be incorporated into symbols when encoding meshes described herein using one or more techniques described in U.S. patent application Ser. No. 18/438,702, entitled “SYSTEMS AND METHODS FOR IMPROVING COMPRESSION OF STRUCTURED DATA IN THREE-DIMENSIONAL APPLICATIONS,” filed Feb. 12, 2024, the content of which is hereby incorporated by reference herein in its entirety. In some implementations, operator application component 120 may be configured to choose the largest/longest side of the triangle to be a splitting side. Then, operator application component 120 may be configured to take centers of each of two sub-triangles for a result of split. Then, operator application component 120 may be configured to determine that the result of split as predicted (X, Y) coordinate pairs for each of the two added vertices C21, C22.

In another example, as shown in FIG. 6B, operator application component 120 may be configured to add three vertices. In some implementations, operator application component 120 may be configured to identify a triangle center (“CT”) and split the triangle into three sub-triangles using segments drawn from the center to each of the triangle's three corners. Then, operator application component 120 may be configured to take centers of each of three sub-triangles as predicted (X, Y) coordinate pairs for each of the three added vertices C31, C32, C33. In various implementations, operator application component 120 may be configured to use one or more other known methods for dividing a triangle into three sub-triangles.

In a yet another example, as shown in FIG. 6C, operator application component 120 may be configured to add four vertices. In some implementations, operator application component 120 may be configured to connect midpoints of three sides of a triangle and create four sub-triangles within the current triangle. Then, operator application component 120 may be configured to take centers of each of four sub-triangles as predicted (X, Y) coordinate pairs for each of the four added vertices C41, C42, C43, and C44.

In various implementations, operator application component 120 may be configured to combine “split” techniques described herein to support added vertices. For example, in some implementations, operator application component 120 may be configured to split a triangle into two and then split both of the two sub-triangles into three, to obtain predicted (X, Y) coordinate pairs for six added vertices.

In some implementations, for multiple added vertices, operator application component 120 may be configured to calculate a prediction for a Z-coordinate using other methods described herein (e.g., as described herein with respect to the “add vertex” operator).

In some implementations, after adding one or more vertices, operator application component 120 may be configured to further adjust a traversing order O[i-1] for future traversing and include additional information regarding added triangles (or vertices) into the traversing order. In some implementations, operator application component 120 may be configured to identify triangles that are adjacent in the traversing order. For example, operator application component 120 may be configured to identify adjacent triangles in the traversing order that share edges with each other. In some implementations, operator application component 120 may be configured to handle or process adding to a traversing order O[i-1] triangles created by adding multiple vertices to the same triangle, “as if” vertices are added one at a time.

In other implementations, after adding one or more vertices, operator application component 120 may be configured to modify the height map to account for changing heights due to the changed geometry. For example, if operator application component 120 adds a vertex, then the surface (including the vertex) of the mesh may rise. The height map may now be modified to include changes reflecting the raised surface and reduced heights over the affected triangle accordingly). Then, operator application component 120 may be configured to generate an updated normal map, which, in turn, may be used as a reference image for compressing normal map N[i-1]. In some implementations, the updated normal map be generated and/or used as a reference image using one or more techniques described in U.S. patent application Ser. No. 18/425,315, entitled “SYSTEMS AND METHODS FOR CREATING EFFICIENT PROGRESSIVE IMAGES,” filed Jan. 29, 2024, the contents of which are hereby incorporated by reference herein in their entirety.

In some implementations, operator application component 120 may be configured to apply a “move vertex” operator to a mesh. For example, operator application component 120 may be configured to apply a “move vertex” operator to a mesh M[i]. For example, operator application component 120 may be configured to apply “move vertex” operator to the processing mesh M[i] by specifying a move for each one of the vertices in the triangle. In such an implementation, operator application component 120 may be configured to encode an index of the vertex within the triangle and distance information indicating how much the vertex of the triangle needs to be moved.

In some implementations, a number of potential vertices may be reduced by enforcing a restriction. For example, the restriction may be that only vertices that first appeared within a current triangle (in the sense of traversing the mesh according to O[i-1]) may be moved, and that the index of potentially-movable vertex is encoded rather than the index of the vertex within the triangle. In some implementations, mesh encoding component 118 may be configured to avoid encoding vertex indexes at all. For example, if all vertices are moved-which may happen, for example, when encoding “morphed meshes” as described herein-all vertices may need to be moved.

In some implementations, per-triangle (as well as per-edge or per-vertex) sequences of operators may be represented “as if” they correspond to an array of JSON-like structures. For example, in such cases, mesh encoding component 118 may be configured to use as an array of per-triangle (or per-edge or per-vertex) structures each having an array of additional_quantization_bits, and having an array of added_vertices, and having an array of moved_vertices. In such implementations, mesh encoding component 118 may be configured to encode/compress this structure using entropy encoding and/or other techniques described in U.S. patent application Ser. No. 18/438,702, entitled “SYSTEMS AND METHODS FOR IMPROVING COMPRESSION OF STRUCTURED DATA IN THREE-DIMENSIONAL APPLICATIONS,” filed Feb. 12, 2024, the content of which is hereby incorporated by reference herein in its entirety.

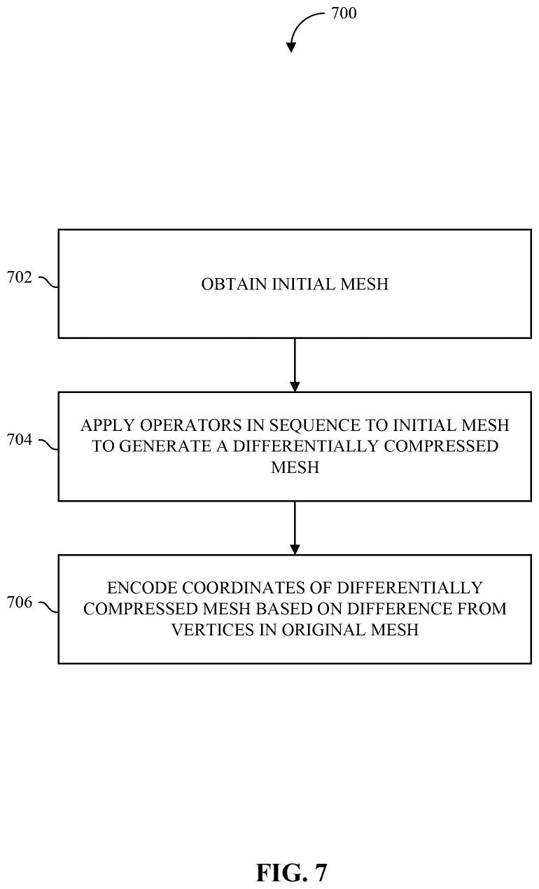

As described herein, a subsequent mesh M[i-1] may be created based on a previous mesh M[i] and a previous traversing order O[i], plus optionally one or more of a previous height map H[i] and a previous normal map n[i]. In some implementations, the end result may not be a “progressive mesh” as described herein, but may instead produce a “differentially compressed mesh” (which corresponds to a compressed sequence of per-triangle or per-edge or per-vertex operators as described above) from an previous mesh (M[i]). To define an original traversing order (which would be used to define O[i-1] and O[i]), any deterministic traversing method may be used, including but not limited to Edgebreaker traversing. Then, on the decompressing/decoding side, a traversing order may be derived from a previous mesh M[i] which may be used as a reference (using the same deterministic traversing method which was used on the compressing side) and then the differentially compressed mesh may be applied to the reference mesh to obtain the original mesh. In various implementations, “differentially compressed meshes” may be used to compress meshes which have the same topology but slightly-moved vertex coordinates. Such meshes may be referred to herein as “morphed meshes.” In such cases, the “reference mesh” may be a “base” (non-morphed) mesh, and the “differentially compressed mesh” may be a sequence of per-vertex “move vertex” operators (in some embodiments, it may be per-edge or per-triangle operators). The method for compressing meshes using differential mesh compression is described further herein with respect to process 700 depicted in FIG. 7. In some implementations, meshes may differentially compressed and/or decompressed using one or more techniques described in U.S. patent application Ser. No. 18/425,315, entitled “SYSTEMS AND METHODS FOR CREATING EFFICIENT PROGRESSIVE IMAGES,” filed Jan. 29, 2024, the contents of which are hereby incorporated by reference herein in their entirety.

In some implementations, the one or more techniques described herein may utilize levels of detail (or LODs). For example, in some implementations, LODs may be embedded into a compressor and/or decompressor, stored within electronic storage 130, and/or otherwise accessible to components of system 100 during compression and/or decompression. For example, in some implementations, these LODs may comprise well-known LODs that may be used as a reference for compression or as a reference mesh without including the well-known in the stream. In some embodiments, differences between vertices of mesh M[i-1] and vertices of a well-known LOD may be encoded in a differential manner, as described herein with respect to process 700 depicted in FIG. 7. Accordingly, the LOD may be used as a reference mesh when differentially encoding a mesh. In some implementations, the LOD used as a reference mesh may not correspond to a lowest-LOD (LOD[Last]), but instead to a higher LOD (all the way up to LOD[0]). In such implementations, both M[i] and the LOD may be used to compress a mesh M[i-1]. For example, triangles may still be traversed in the order of O[i], but then closest vertices of the LOD to each of the vertices of a triangle may be found (in the sense of traversing over O[i]). If the same vertex qualifies as closest to more than one vertex of the triangle, a second-closest vertex may be used. Then, vertices may be enumerated which are topologically within the triangle formed by well-known LOD vertices (this may be the same on both encoding and decoding sides), and find the one which is the closest to the added vertex. In this manner, the index of the closest LOD vertex within the enumeration may be encoded along with a distance of the added vertex from the LOD vertex.

In some implementations, the one or more techniques described herein may be utilized to compress skinned meshes. A “skinned mesh” may comprise a mesh that has a skeleton and bones that can be used to animate the vertices of the geometry (as described, for example, in “Skinned Mesh Animation Using Matrices” by Bruce J. Veazie, which can be found at https://www.gamedev.net/tutorials/programming/graphics/skinned-mesh-animation-using-matrices-r3577/). Each of the vertices of a skinned mesh may correspond to up to four or more “(bone_index, bone_weight)” pairs. These “(bone_index, bone_weight)” pairs define up to four skinning bone weights that may affect a vertex in a mesh. The “bone_index” may comprise the index for a given bone, or otherwise identify a bone, and the “bone_weight” may indicate a skinning weight for that bone. In various implementations, an initial skinned mesh may be compressed using one or more techniques described herein, with the addition of a per-vertex array of (bone_index, bone_weight) pairs. Each vertex may be said to have a “bone_weight” for every “bone_index”, but only those that are non-zero (and/or the highest ones) may be encoded. In some implementations, the initial skinned mesh may comprise an LOD mesh.

In various implementations, (bone_index, bone_weight) pairs for skinned meshes may be compressed using a per-bone prediction function. For example, a per-bone prediction function over 3D space may be defined that corresponds to a Gaussian function (described by zero expected value and some variance), a 3D vector (described by its origin and direction), and/or a radius of a cylinder. To apply the per-bone function to a vertex, whether the vertex is within the cylinder (defined by a 3D vector and radius) may be calculated, the vertex may be projected to the 3D vector, a distance of the projection to the origin may be calculated. This distance may be used as a prediction for the weight of the particular bone to the vertex. In some implementations, the per-bone prediction function may be defined by finding the best approximation (e.g., minimizing mean square error) of the prediction function given the bones in the original skinned mesh. In some implementations, parameters of these functions may be compressed and included as a part of the encoded/compressed stream. After applying the per-bone function to each vertex, a “bone_weight” for all the bones for each of the vertices may be calculated. These calculated “bone_weights” may then be sparce-encoded by finding which bones have a “bone_weight” values above certain threshold and using those bones as a “prediction function” for the array of (bone_index, bone_weight) pairs, encoding only differences from the “prediction function”.

In another embodiment, when compressing/encoding a difference from mesh M[i], values for each skinned mesh “bone_weight” may be predicted and only the differences from the predicted “bone_weight” may be encoded. For example, when adding a vertex, “bone_weights” for the corners of a triangle may be linearly interpolated for an (X, Y) point within the triangle. Then, we may use this linear interpolation as a “prediction function” for respective bone_weights of the added function, encoding only differences from the “prediction function” (for example, within “add vertex” operator). In another example, when adding a vertex, the closest vertex of the well-known LOD may be identified and the bones (as in (bone_index,bone_weight)) in vertex of the skinned mesh may be encoded only as the difference from the bones in that vertex.

In some implementations, when using a method which refers to a “difference from some mesh”, a well-known LOD may be used in lieu of this “some mesh”; in some of such implementations, whenever needing to refer to the vertex of the “some mesh”, a closest-vertex-of-well-known-LOD may be used instead. In some implementations, a “closest” vertex may be found from any point of interest which is within current scope (for example, when adding a vertex to a triangle, any of the triangle vertices and any of triangle centers may be considered as “points of interest” and may be used to find the “closest” vertex within the well-known LOD).

In some implementations, meshes described herein may be compressed in a non-incremental manner. In other words, these meshes may be compressed (or encoded) “from scratch.” In some implementations, meshes described herein may be compressed in a non-incremental manner as described in “3D Compression Made Simple: Edgebreaker on a Corner-Table” by Jarek Rossignac et al., published in January 2001 and presented at the Shape Modeling International Conference in Genoa, Italy (May 7-11, 2001), the contents of which are herein incorporated by reference in their entirety. For example, meshes described herein may be compressed in a non-incremental manner using some traversing algorithm (such as Edgebreaker) for traversing and encoding topology of a mesh and using a parallelogram predictor to predict coordinates of new vertices as the new vertices are added to the mesh. In some implementations, this technique may be improved by using parallelogram predictor to predict an (X,Y) coordinate pair of a new vertex, and using coordinates of the vertices used by the parallelogram predictor and/or their respective normal vectors to calculate an algebraic surface (such as 2^{nd}- or 3^{rd}-order surface) which goes through these three vertices and has appropriate normals at the respective points. When this surface is calculated, an intersection of the normal vector to the parallelogram at the point (X, Y) and the calculated surface may be found, and the distance between this intersection and the plane of the parallelogram may comprise the predicted Z-coordinate for the encoding.

Electronic storage 130 may include electronic storage media that electronically stores and/or transmits information. The electronic storage media of electronic storage 130 may be provided integrally (i.e., substantially nonremovable) with one or more components of system 100 and/or removable storage that is connectable to one or more components of system 100 via, for example, a port (e.g., USB port, a Firewire port, and/or other port) or a drive (e.g., a disk drive and/or other drive). Electronic storage 130 may include one or more of optically readable storage media (e.g., optical disks and/or other optically readable storage media), magnetically readable storage media (e.g., magnetic tape, magnetic hard drive, floppy drive, and/or other magnetically readable storage media), electrical charge-based storage media (e.g., EPROM, EEPROM, RAM, and/or other electrical charge-based storage media), solid-state storage media (e.g., flash drive and/or other solid-state storage media), and/or other electronically readable storage media. Electronic storage 130 may be a separate component within system 100, or electronic storage 130 may be provided integrally with one or more other components of system 100 (e.g., computer system 110 or processor 112). Although electronic storage 130 is shown in FIG. 1 as a single entity, this is for illustrative purposes only. In some implementations, electronic storage 130 may comprise a plurality of storage units. These storage units may be physically located within the same device, or electronic storage 130 may represent storage functionality of a plurality of devices operating in coordination.

Electronic storage 130 may store software algorithms, information determined by processor 112, information received remotely, and/or other information that enables system 100 to function properly. For example, electronic storage 130 may store information relating to one or more three-dimensional models, one or more existing compression methods used to compress meshes, one or more existing decompression methods used to decompress meshes, information associated with different levels of detail (LODs), and/or other information related to the systems and methods described herein.

Client computing device(s) 140 (also interchangeably referred to herein as client computing device 140, client computing devices 140, or one or more client computing devices 140) may be used by users of system 100 to interface with system 100. Client computing device(s) 140 may be configured as a server device (e.g., having one or more server blades, processors, etc.), a gaming console, a handheld gaming device, a personal computer (e.g., a desktop computer, a laptop computer, etc.), a smartphone, a tablet computing device, an Internet of Things (IoT) device, a wearable device, and/or other devices that can be programmed to interface with computer system 110.

FIG. 3 illustrates an example of a process 300 for performing progressive mesh compression for a three-dimensional model based on a superset relationship between consecutive meshes, according to one or more aspects described herein. The operations of process 300 presented below are intended to be illustrative and, as such, should not be viewed as limiting. In some implementations, process 300 may be accomplished with one or more additional operations not described, and/or without one or more of the operations discussed. In some implementations, two or more of the operations of process 300 may occur substantially simultaneously. The described operations may be accomplished using some or all of the system components described in detail above.

In an operation 302, process 300 may include obtaining sequence of meshes for a three-dimensional model. In various implementations, the sequence of meshes may comprise a sequence of LODs that themselves may include meshes, textures, and/or normal maps. In various implementations, the sequence of meshes may be generated based on an initial mesh, wherein the sequence of meshes comprises a sequence of meshes that gradually increase in detail from the initial mesh to a highest-quality mesh. In some implementations, operation 302 may be performed by a processor component the same as or similar to progressive mesh creation component 116 (shown in FIG. 1 and described herein).

In an operation 304, process 300 may include first encoding an initial (or base) mesh of the sequence of meshes into a data stream. For example, the initial mesh (“M[Last]”) may be compressed using an existing compression method and put into an intermediate symbol stream. In some implementations, per-triangle (per-edge, per-vertex) operators described herein may be applied to the initial mesh prior to encoding the initial mesh. In some implementations, operation 304 may be performed by one or more processor components the same as or similar to mesh encoding component 118, operator application component 120, and/or coordinate prediction component 122 (shown in FIG. 1 and described herein).

In operations 306-316, process 300 may include encoding subsequent meshes and generating an output to a data stream. For example, using operations 306-316, process 300 may encode subsequent meshes “M[i-1]” and “M[i]” into the intermediate symbol stream. As used herein, “M[i]” may be used to denote a subsequent mesh after an initial (or base) mesh, and “M[i-1]” may be used to denote a subsequent mesh after “M[i]”. In some implementations, operation 306-316 may be performed by one or more processor components the same as or similar to mesh encoding component 118, operator application component 120, and/or coordinate prediction component 122 (shown in FIG. 1 and described herein).

In an operation 306, process 300 may include determining whether vertices of each subsequent mesh are a superset of the vertices of a previous mesh. For example, whether the vertices of a subsequent mesh M[i-1] are a superset (or mostly a superset of) the vertices of the mesh M[i] may be determined. In some implementations, if decimation without changing vertex coordinates (such as described in “A General Framework for Mesh Decimation” by Leif Kobbelt et al., which was published in Proceedings of the Graphics Interface in 1998) was used to obtain mesh M[i], the vertices which exist in both the mesh M[i-1] and M[i] are likely to be the same or similar. In other implementations, for example, if topologically-changing re-meshing was used to generate a subsequent mesh (e.g., M[i]), the vertices of the meshes M[i-1] and M[i] are likely to be different.

If the vertices of the mesh M[i-1] are not determined to be a superset of the vertices of the mesh M[i], process 300 may proceed to operation 307. In an operation 307, process 300 may include encoding the mesh M[i-1] by using a non-incremental mesh compression technique, such as Draco compression and/or one or more other similar non-incremental mesh compression techniques. After encoding the mesh using non-incremental mesh compression in operation 307, process 300 may proceed to operation 314 and determine whether the mesh being processed (i.e., analyzed and encoded) is the final mesh, as described herein.

In some implementations, when encoding is performed using non-incremental mesh compression (e.g., when encoding a subsequent mesh M[i-1] with vertices that are not a superset (or mostly a superset of) the vertices of previous mesh M[i]), operation 307 may include performing a quantization or rounding process with a predefined number of bits. In some implementations, some meshes do not need to be compressed losslessly. For example, when compressing meshes for use to render a 3D object in an online video game, some loss of attribute precision may be acceptable to gain faster transmission time. In such cases, the number of bits may be determined based on the LOD associated with a mesh or sequence of meshes. For example, quantization and/or rounding may be applied to ensure that LOD[Last] has precision of 6 bits per vertex, that LOD[Last-1] has precision of 7 or 8 bits per vertex, and so on.

If vertices of the mesh M[i-1] are determined to be a superset of the vertices of the mesh M[i], process 300 may proceed to operation 308. For example, a traversing order may be defined as described herein with respect to mesh encoding component 118. In some implementations, the traversing order may be derived from a mesh being traversed or a subsequent or adjacent mesh. In other implementations, the traversing order may be based on a compression method used to compress the initial mesh.

In an operation 310, process 300 may determine operators which have to be applied to the mesh M[i] to produce mesh M[i-1]. For example, if during decimation from M[i-1] to M[i] a vertex was removed, operation 310 may add an “add vertex” operator, and then multiple “add vertex” operators may be combined into “add multiple vertices” operator. In addition, an “add quantization bits” operator may be added; some other operators may be added in a similar manner as well (for example, “move vertex” operator may be added based on decimation process which was used to obtain M[i] from M[i-1], which similar to adding “add vertex” operator as described above). In some implementations, the coordinates of vertices within respective operators may be defined (and encoded) using a delta value (difference) from the predicted data generated by the prediction function. In various implementations, the predicted data may include X-Y coordinates based on a normal map using a previous mesh. In various implementations, the predicted data may include X-Y coordinates based on one of local maximums of the normal map. In various implementations, the vertex may include X-Y coordinates based on a center of a triangle of the progressive mesh. In various implementations, the operators may include adding n vertices, the operators may obtain n sub-triangles by splitting a triangle of the progressive mesh, and X-Y coordinates of the N vertices may be calculated from the n sub-triangles (as shown in FIGS. 6A-C and described herein). In various implementations, the vertex may include a Z-coordinate based on a 3D spline over existing vertices. In some implementations, the vertex may include a Z-coordinate based on Bezier triangles and/or N-patches. In other implementations, the vertex may include a Z-coordinate based on a normal map. For each triangle, zero or more of the operators described herein may be specified. In various implementations, when applied to the mesh in sequence, the operators may generate a progressive mesh including a vertex.

In operation 312, process 300 may include encoding the mesh and/or the operators applied to the mesh in sequence. In various implementations, encoding meshes may comprise encoding operators applied to the mesh in sequence. In various implementations, each of the operators in sequence may be encoded using intermediate symbols. In some implementations, the intermediate symbols may be pre-defined. In some implementations, each of the operators in sequence may include operator-specific data. In one example, there may be “add quantization bits” operator adding one or more bits to each and every coordinate to each and every vertex in the mesh M[i]; in such a case, operator-specific data for this operator may include a list of all the bits to be added (in vertex traversing order). In various implementations, operators may be encoded using one or more existing entropy encoding methods. For example, the one or more entropy encoding methods may comprise Huffman encoding, arithmetic coding, one of the asymmetric numeral systems (ANS) family of entropy encoding methods, and/or one or more other entropy encoding methods. In some implementations, the progressive mesh may be processed in a predetermined traversing order. In such implementations, the decompression process may be traversed in an order which is compressed (or derived) from the mesh or from the existing method.

In operation 314, process 300 may include determining whether a mesh being processed (i.e., analyzed and encoded) is the final mesh. For example, whether the mesh is the final mesh in the sequence of meshes obtained in operation 302 may be determined. If the mesh is not the final mesh, process 300 may return to operation 306 and process the next mesh in the sequence of meshes. If the mesh is the final mesh, process 300 may proceed to operation 316. In an operation 316, process 300 may include generating an output and sending the output (i.e., the encoded mesh) to a data stream. For example, the data stream may comprise an intermediate symbol stream and sending the output to a data stream may comprise emitting the encoded mesh to an intermediate symbol stream.

FIG. 7 depicts a flow diagram of an example of a process 700 for compressing meshes using differential mesh compression, according to one or more aspects described herein. The operations of process 700 presented below are intended to be illustrative and, as such, should not be viewed as limiting. In some implementations, process 700 may be accomplished with one or more additional operations not described, and/or without one or more of the operations discussed. In some implementations, two or more of the operations of process 700 may occur substantially simultaneously. The described operations may be accomplished using some or all of the system components described in detail above.

In an operation 702, the process 700 may include obtaining an initial mesh. In some implementations, the initial mesh may be generated using one or more techniques described herein. In some implementations, operation 702 may be performed by a processor component the same as or similar to progressive mesh creation component 116 (shown in FIG. 1 and described herein).

In an operation 704, the process 700 may include applying one or more per-vertex (or per-triangle or per-edge) operators to the initial mesh to generate a differentially compressed mesh, which may be a “morphed mesh.” As used herein, a “morphed mesh” may comprise a mesh which have the same topology as previous mesh but with slightly-moved vertex coordinates. In various implementations, the differentially compressed mesh may include a one or more vertices. In some implementations, the differentially compressed mesh may be processed in a predetermined traversing order. In such implementations, the mesh may be traversed in an order which is derived from the initial mesh. In some implementations, “move vertex” operator may be used to specify the difference between initial mesh and “morphed mesh”. In some implementations, the sequence of per-vertex (per-edge, per-triangle) operators applied to the initial mesh may represent the differentially compressed mesh. In some implementations, operation 704 may be performed by one or more processor components the same as or similar to mesh encoding component 118, operator application component 120, and/or coordinate prediction component 122 (shown in FIG. 1 and described herein).

In an operation 706, the process 700 may include encoding the sequence of per-vertex (per-edge, per-triangle) operators applied to the initial mesh into an intermediate symbol stream. In various implementations, coordinates of the differentially compressed mesh may be encoded as a difference from the vertices of the initial mesh. For example, coordinates corresponding to moved vertices in the differentially compressed mesh may be encoded using a delta value (or difference) from corresponding vertices in the initial mesh. In various implementations, the delta value may be calculated differentially from the previous delta value. For example, the difference between the coordinates of a moved vertex and coordinates of the vertex in the initial mesh may be encoded based on a previous difference encoded. In some implementations, the indexes of the moved vertices may not be encoded at all. In some implementations, operation 706 may be performed by a processor component the same as or similar to mesh encoding component 118 (shown in FIG. 1 and described herein).

The methods disclosed herein comprise one or more steps or actions for achieving the described method. The method steps and/or actions may be interchanged with one another without departing from the scope of the present invention. In other words, unless a specific order of steps or actions is required for proper operation of the embodiment, the order and/or use of specific steps and/or actions may be modified without departing from the scope of the present invention.

Implementations of the disclosure may be made in hardware, firmware, software, or any suitable combination thereof. Aspects of the disclosure may be implemented as instructions stored on a machine-readable medium, which may be read and executed by one or more processors. A machine-readable medium may include any mechanism for storing or transmitting information in a form readable by a machine (e.g., a computing device). For example, a tangible computer readable storage medium may include read only memory, random access memory, magnetic disk storage media, optical storage media, flash memory devices, and others, and a machine-readable transmission media may include forms of propagated signals, such as carrier waves, infrared signals, digital signals, and others. Firmware, software, routines, or instructions may be described herein in terms of specific exemplary aspects and implementations of the disclosure, and performing certain actions.

The various illustrative logical blocks, modules, circuits, and algorithm steps described in connection with the embodiments disclosed herein may be implemented as electronic hardware, computer software, or combinations of both. To illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. The described functionality can be implemented in varying ways for each particular application-such as by using any combination of digital processors, analog processors, digital circuits designed to process information, central processing units, graphics processing units, microcontrollers, microprocessors, field programmable gate arrays (FPGAs), application specific integrated circuits (ASICs), a System on a Chip (SoC), and/or other mechanisms for electronically processing information—but such implementation decisions should not be interpreted as causing a departure from the scope of the present invention.

The description of the functionality provided by the different computer-readable instructions described herein is for illustrative purposes, and is not intended to be limiting, as any of instructions may provide more or less functionality than is described. For example, one or more of the instructions may be eliminated, and some or all of its functionality may be provided by other ones of the instructions. As another example, processor(s) 112 may be programmed by one or more additional instructions that may perform some or all of the functionality attributed herein to one of the computer-readable instructions.

The various instructions described herein may be stored in electronic storage, which may comprise random access memory (RAM), read only memory (ROM), and/or other memory. In some implementations, the various instructions described herein may be stored in electronic storage of one or more components of system 100 and/or accessible via a network (e.g., via the Internet, cloud storage, and/or one or more other networks). The electronic storage may store the computer program instructions (e.g., the aforementioned instructions) to be executed by processor(s) 112 as well as data that may be manipulated by processor(s) 112. The electronic storage may comprise floppy disks, hard disks, optical disks, tapes, or other storage media for storing computer-executable instructions and/or data.

Although illustrated in FIG. 1 as a single component, computer system 110 and client computing device(s) 140 may each include a plurality of individual components (e.g., computer devices) each programmed with at least some of the functions described herein. In this manner, some components of computer system 110 and/or associated client computing device(s) may perform some functions while other components may perform other functions, as would be appreciated. Furthermore, it should be appreciated that although the various instructions are illustrated in FIG. 1 as being co-located within a single processing unit, in implementations in which processor(s) 112 include multiple processing units, one or more instructions may be executed remotely from the other instructions.

Although processor computer system 110, electronic storage 130, and client computing device(s) 140 are shown to be connected to interface 102 in FIG. 1, any communication medium may be used to facilitate interaction between any components of system 100. One or more components of system 100 may communicate with each other through hard-wired communication, wireless communication, or both. In various implementations, one or more components of system 100 may communicate with each other through a network. For example, computer system 110 may wirelessly communicate with electronic storage 130. By way of non-limiting example, wireless communication may include one or more of radio communication, Bluetooth communication, Wi-Fi communication, cellular communication, infrared communication, or other wireless communication. Other types of communications are contemplated by the present disclosure.

Reference in this specification to “one implementation”, “an implementation”, “some implementations”, “various implementations”, “certain implementations”, “other implementations”, “one series of implementations”, or the like means that a particular feature, design, structure, or characteristic described in connection with the implementation is included in at least one implementation of the disclosure. The appearances of, for example, the phrase “in one implementation” or “in an implementation” in various places in the specification are not necessarily all referring to the same implementation, nor are separate or alternative implementations mutually exclusive of other implementations. Moreover, whether or not there is express reference to an “implementation” or the like, various features are described, which may be variously combined and included in some implementations, but also variously omitted in other implementations. Similarly, various features are described that may be preferences or requirements for some implementations, but not other implementations.

The language used herein has been principally selected for readability and instructional purposes, and it may not have been selected to delineate or circumscribe the inventive subject matter. Other implementations, uses and advantages of the invention will be apparent to those skilled in the art from consideration of the specification and practice of the invention disclosed herein. The specification should be considered exemplary only, and the scope of the invention is accordingly intended to be limited only by the following claims.

1. A computer-implemented method of performing progressive mesh compression of computer-generated three-dimensional models, the method comprising:
obtaining an initial mesh for a three-dimensional model;
encoding the initial mesh into an intermediate symbol stream;
determining that a subsequent mesh has vertices which is a superset of the vertices of at least one mesh adjacent the subsequent mesh;
responsive to determining that the subsequent mesh is a superset of at least one mesh adjacent the subsequent mesh, determining operators which need to be applied to triangles, edges, or vertices of the subsequent mesh, wherein applying the operators in sequence to the subsequent mesh produces a progressive mesh; and
encoding the operators to the subsequent mesh in sequence into the intermediate symbol stream.

2. The computer-implemented method of claim 1, wherein the triangles of the subsequent mesh are traversed in an order derived from the subsequent mesh.

3. The computer-implemented method of claim 1, wherein the initial mesh is compressed using an existing compression method, and wherein the triangles of the subsequent mesh are traversed in an order based on the existing compression method.

4. The computer-implemented method of claim 1, wherein at least one of the operators includes adding quantization bits for a vertex of a triangle of the subsequent mesh.

5. The computer-implemented method of claim 1, wherein at least one of the operators includes adding a vertex or moving a vertex.

6. The computer-implemented method of claim 5, the method further comprising encoding coordinates of an added or moved vertex as a difference between the coordinates of the added or moved vertex and predicted coordinates calculated using a prediction function.

7. The computer-implemented method of claim 6, wherein an (X,Y) coordinate pair of the predicted coordinates is calculated based on a normal map using a previous mesh.

8. The computer-implemented method of claim 7, wherein the (X,Y) coordinate pair of the predicted coordinates is identified based on a local maximum of the normal map.

9. The computer-implemented method of claim 6, wherein an (X,Y) coordinate pair of the predicted coordinates is calculated based on a center of a triangle of the subsequent mesh.

10. The computer-implemented method of claim 6, wherein at least one of the operators includes adding multiple vertices, wherein the method further comprises encoding coordinates of each added vertex as a difference between the coordinates of the added vertex and predicted coordinates, wherein the predicted coordinates are determined by splitting a triangle into two or more sub-triangles and using (X,Y) coordinates for centers of each of the two or more sub-triangles as the predicted coordinates.

11. The computer-implemented method of claim 6, wherein a Z-coordinate of the predicted coordinates is calculated based on a three-dimensional spline over existing vertices of the subsequent mesh.

12. The computer-implemented method of claim 6, wherein a Z-coordinate of the predicted coordinates is calculated using Bezier triangles and/or N-patches.

13. The computer-implemented method of claim 6, wherein a Z-coordinate of the predicted coordinates is calculated based on a normal map.

14. The computer-implemented method of claim 1, the method further comprising encoding the operators applied to the subsequent mesh using at least one entropy encoding method.

15. The computer-implemented method of claim 14, wherein the at least one entropy encoding method comprises Huffman encoding, arithmetic coding, or one of the asymmetric numeral systems (ANS) family of entropy encoding methods.

16. The computer-implemented method of claim 1, the method further comprising:
determining that a second subsequent mesh is not a superset of at least one mesh adjacent the second subsequent mesh; and
responsive to determining that the second subsequent mesh is not a superset of at least one mesh adjacent the second subsequent mesh, encoding the second subsequent mesh using a non-incremental mesh compression method.

17. The computer-implemented method of claim 16, wherein the non-incremental mesh compression method comprises an Edgebreaker compression method.

18-23. (canceled)

24. A system for performing progressive mesh compression of computer-generated three-dimensional models, the system comprising:
one or more processors configured by computer readable instructions to:
obtain an initial mesh for a three-dimensional model;
encode the initial mesh into an intermediate symbol stream;
determine that a subsequent mesh has vertices which is a superset of the vertices of at least one mesh adjacent the subsequent mesh;
responsive to the determination that the subsequent mesh is a superset of at least one mesh adjacent the subsequent mesh, determine operators which need to be applied to triangles, edges, or vertices of the subsequent mesh, wherein applying the operators in sequence to the subsequent mesh produces a progressive mesh; and
encode the operators to the subsequent mesh in sequence into the intermediate symbol stream.

25. The system of claim 24, wherein the triangles of the subsequent mesh are traversed in an order derived from the subsequent mesh.

26. The system of claim 24, wherein the initial mesh is compressed using an existing compression method, and wherein the triangles of the subsequent mesh are traversed in an order based on the existing compression method.

27. The system of claim 24, wherein at least one of the operators includes adding quantization bits for a vertex of a triangle of the subsequent mesh.

28. The system of claim 24, wherein at least one of the operators includes adding a vertex or moving a vertex.

29. The system of claim 28, wherein the one or more processors are further configured to encode coordinates of an added or moved vertex as a difference between the coordinates of the added or moved vertex and predicted coordinates calculated using a prediction function.

30. The system of claim 29, wherein an (X,Y) coordinate pair of the predicted coordinates is calculated based on a normal map using a previous mesh.

31. The system of claim 30, wherein the (X,Y) coordinate pair of the predicted coordinates is identified based on a local maximum of the normal map.

32. The system of claim 29, wherein an (X,Y) coordinate pair of the predicted coordinates is calculated based on a center of a triangle of the subsequent mesh.

33. The system of claim 29, wherein at least one of the operators includes adding multiple vertices, wherein the one or more processors are further configured to encode coordinates of each added vertex as a difference between the coordinates of the added vertex and predicted coordinates, wherein the predicted coordinates are determined by splitting a triangle into two or more sub-triangles and using (X,Y) coordinates for centers of each of the two or more sub-triangles as the predicted coordinates.

34. The system of claim 29, wherein a Z-coordinate of the predicted coordinates is calculated based on a three-dimensional spline over existing vertices of the subsequent mesh.

35. The system of claim 29, wherein a Z-coordinate of the predicted coordinates is calculated using Bezier triangles and/or N-patches.

36. The system of claim 29, wherein a Z-coordinate of the predicted coordinates is calculated based on a normal map.

37. The system of claim 24, wherein the one or more processors are further configured to encode the operators applied to the subsequent mesh using at least one entropy encoding method.

38. The system of claim 37, wherein the at least one entropy encoding method comprises Huffman encoding, arithmetic coding, or one of the asymmetric numeral systems (ANS) family of entropy encoding methods.

39. The system of claim 24, wherein the one or more processors are further configured to:
determine that a second subsequent mesh is not a superset of at least one mesh adjacent the second subsequent mesh; and
responsive to the determination that the second subsequent mesh is not a superset of at least one mesh adjacent the second subsequent mesh, encode the second subsequent mesh using a non-incremental mesh compression method.

40. The system of claim 39, wherein the non-incremental mesh compression method comprises an Edgebreaker compression method.

41-46. (canceled)
